(19) United States
(12) Patent Application Publication
(10) Pub. No.: US 2017/0054425 A1
(43) Pub. Date: Feb. 23, 2017

(54) COMMON-MODE COMPENSATION TECHNIQUE FOR PROGRAMMABLE GAIN AMPLIFIERS

(71) Applicant: QUALCOMM Incorporated, San Diego, CA (US)

(72) Inventors: Srinidhi Koushik Kanagal Ramesh, Bengaluru (IN); Wenchang Huang, San Diego, CA (US); Meysam Azin, San Diego, CA (US)

(21) Appl. No.: 14/982,612

(22) Filed: Dec. 29, 2015

Related U.S. Application Data
(60) Provisional application No. 62/208,159, filed on Aug. 21, 2015.

(51) Int. Cl. H03G 3/30; H03F 3/185

(52) U.S. Cl. CPC H03G 3/3005; H03F 3/185; H03F 2200/03; H03F 2203/45116

(57) ABSTRACT

Certain aspects of the present disclosure provide methods and apparatus for adjusting a bandwidth of an amplifier (e.g., a programmable gain amplifier (PGA)). In certain aspects, the PGA generally includes at least one amplification stage having an input and an output, a plurality of compensation capacitors, and at least one first switch configured to selectively couple at least one capacitor of the plurality of compensation capacitors between the input and the output of the at least one amplification stage. In certain aspects, the amplifier includes at least one second switch configured to selectively couple the at least one capacitor to a node such that the at least one capacitor is coupled to only one of the output or the node, where a voltage at the node is a differential mode (DM) reference potential for the amplification stage.

### CROSS-REFERENCE TO RELATED APPLICATION

The present application claims priority to U.S. Provisional Application Ser. No. 62/208,159, entitled “COMMON-MODE COMPENSATION TECHNIQUE FOR PROGRAMMABLE GAIN AMPLIFIERS,” filed Aug. 21, 2015, which is assigned to the assignee of the present application and hereby expressly incorporated by reference herein in its entirety.

### TECHNICAL FIELD

Certain aspects of the present disclosure generally relate to electronic circuits and, more particularly, to a programmable gain amplifier (PGA).

### BACKGROUND

Digital audio processing may be performed in various devices, such as audio receivers, computers, tablets, smartphones, user terminals, and the like. For digital audio processing, an encoder-decoder (CODEC) may be used to convert analog audio signals to encoded digital signals and vice versa. For example, a CODEC may receive an analog audio signal (e.g., from a microphone), and convert the analog audio signal into a digital signal that can be processed (e.g., digitally filtered) via a digital signal processor (DSP). The CODEC can then convert the processed digital output of the DSP to an analog signal for use by audio speakers, for example, via a digital-to-analog converter (DAC).

### SUMMARY

Certain aspects of the present disclosure generally relate to common-mode compensation techniques for programmable gain amplifiers.

Certain aspects of the present disclosure provide a programmable gain amplifier (PGA). The PGA generally includes at least one amplification stage having an input and an output; a plurality of compensation capacitors; at least one first switch configured to selectively couple at least one capacitor of the plurality of compensation capacitors between the input and the output of the at least one amplification stage; and at least one second switch configured to selectively couple the at least one capacitor to a node, wherein the at least one capacitor is coupled to only one of the output or the node (at a time) and wherein a voltage at the node is a differential mode (DM) reference potential for the at least one amplification stage.

In certain aspects, the DM reference potential is a common-mode (CM) voltage of the PGA. In this case, the PGA further comprises an amplifier coupled to the node and configured to compare the CM voltage of the PGA with a CM reference potential and to adjust the CM voltage of the PGA based on the comparison.

In certain aspects, the PGA further includes a CM amplifier coupled to the node and configured to compare an effective CM voltage of the PGA with a CM reference potential and to adjust the effective CM voltage of the PGA based on the comparison. In certain aspects, the CM amplifier includes a first transistor, wherein a gate of the first transistor is controlled via the CM reference potential; a second transistor, wherein a gate of the second transistor is controlled via a positive differential output of the PGA; and a third transistor, wherein a gate of the third transistor is controlled via a negative differential output of the PGA. In this case, sources of the first, second, and third transistors are coupled to the node, a drain of the second transistor is coupled to a drain of the third transistor, and a voltage at the drains of the second and third transistors is used to adjust the effective CM voltage of the PGA based on the comparison.

According to certain aspects, each of the plurality of compensation capacitors are coupled to the input of the at least one amplification stage through a respective resistor.

According to certain aspects, the at least one first switch and the at least one second switch are controlled based on a gain of the PGA.

According to certain aspects, the PGA further includes at least one gain adjustment capacitor coupled across an input and an output of the PGA. A gain of the PGA may be adjusted by adjusting a capacitance of the at least one gain adjustment capacitor. For certain aspects, the output of the PGA is the output of the at least one amplification stage.

According to certain aspects, the PGA further includes a plurality of resistors coupled across a differential output of the at least one amplification stage. For certain aspects, the node is a node between the plurality of resistors.

According to certain aspects, the plurality of compensation capacitors are configured to increase a phase margin of the PGA.

Certain aspects of the present disclosure provide a method for operating a PGA. The method generally includes adjusting a bandwidth of the PGA by selectively coupling at least one capacitor of a plurality of compensation capacitors between an input and an output of at least one amplification stage of the PGA and selectively coupling the at least one capacitor to a node, wherein the at least one capacitor is coupled to only one of the output or the node and wherein a voltage at the node is a DM reference potential for the at least one amplification stage.

Certain aspects of the present disclosure generally relate to an apparatus for amplifying a signal. The apparatus generally includes means for adjusting a bandwidth of the apparatus by selectively coupling at least one capacitor of a plurality of compensation capacitors between an input and an output of at least one amplification stage of the apparatus and means for selectively coupling the at least one capacitor to a node, wherein the at least one capacitor is coupled to only one of the output or the node and wherein a voltage at the node is a DM reference potential for the at least one amplification stage.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example encoder-decoder (CODEC), in accordance with certain aspects of the present disclosure.

FIG. 2 is a diagram of an example programmable gain amplifier (PGA) with gain control capacitors, in accordance with certain aspects of the present disclosure.

FIG. 3 is a diagram of an example amplifier in the PGA of FIG. 2 where a common-mode (CM) sense node of the amplifier is coupled to differential outputs of the amplifier via resistors, in accordance with certain aspects of the present disclosure.

FIG. 4 is a diagram of an example amplifier in the PGA of FIG. 2 having a CM amplifier configured to effectively sense a CM voltage of the PGA via transistors and adjust the CM voltage based on a reference potential, in accordance with certain aspects of the present disclosure.

FIG. 5 is a flow diagram of example operations for controlling a PGA, in accordance with certain aspects of the present disclosure.

### DETAILED DESCRIPTION

Certain aspects of the present disclosure generally relate to reconfiguring a connection of a differential-mode (DM) Miller capacitor—connected between input and output nodes of an amplification stage in a programmable gain amplifier (PGA)—into a common-mode (CM) Miller capacitor, connected between the input and a node used as a DM reference potential for this (and/or another, different) amplification stage.

Various aspects of the present disclosure are described below. It should be apparent that the teachings herein may be embodied in a wide variety of forms and that any specific structure, function, or both being disclosed herein is merely representative. Based on the teachings herein, one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. Furthermore, an aspect may comprise at least one element of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Audio Processing System

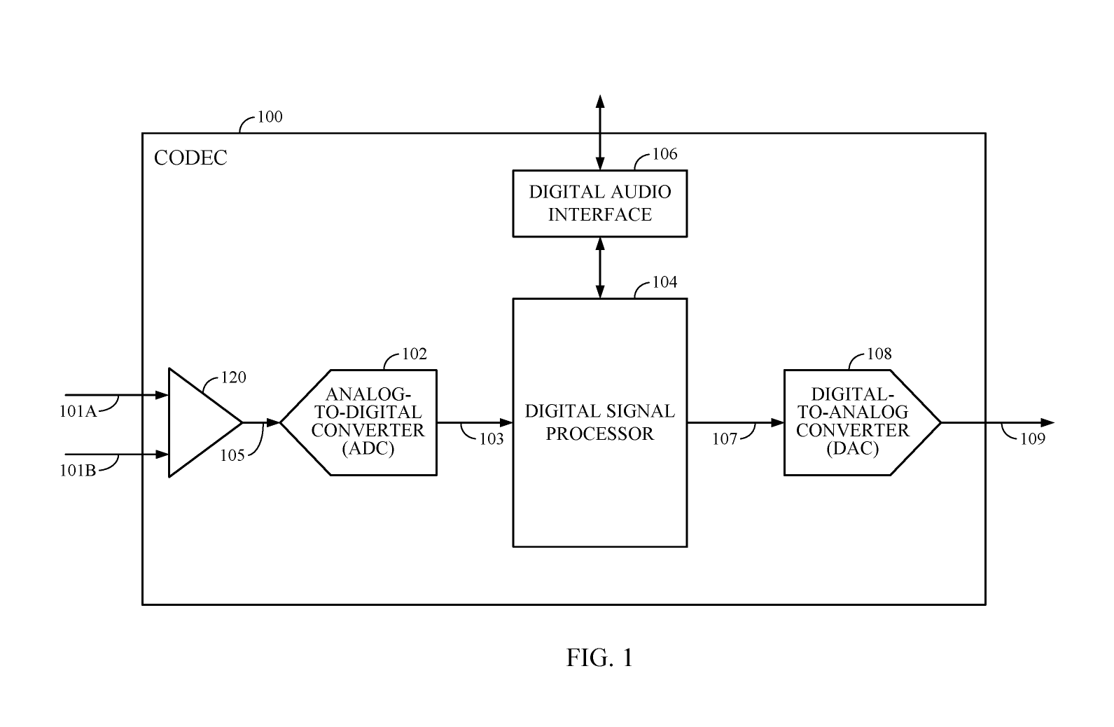

FIG. 1 illustrates an example encoder/decoder (CODEC) 100, according to certain aspects of the present disclosure. The CODEC 100 may receive a differential analog signal having a positive differential signal 101A and a negative differential signal 101B (collectively “differential analog signal 101”), which may be amplified via an amplifier 120. The output of the amplifier 120 may be single-ended, as illustrated in FIG. 1, or differential. The amplified signal 105 may be converted into a digital signal 103 via an analog-to-digital converter (ADC) 102. For example, the differential analog signal 101 input to the amplifier 120 may include an input from a microphone. In certain aspects of the present disclosure, the amplifier 120 may be a programmable gain amplifier (PGA).

The converted digital signal 103 may be sent to a processing system 104 (e.g., a digital signal processor (DSP)), where the processing system 104 may process the digital signal. For example, the processing system 104 may be used for filtering, decimating, adaptive predictive coding, interpolating, and/or mixing the converted digital signal 103, to name a few. The processing system 104 may also receive signals for processing from one or more digital components, such as a digital microphone or a memory, via a digital audio interface 106, for example. The CODEC 100 may also include a digital-to-analog converter (DAC) 108, used to convert the processed digital signals 107 from the processing system 104 to analog signals 109, which may be sent to one or more analog components (e.g., speakers).

### Example Programmable Gain Amplifier

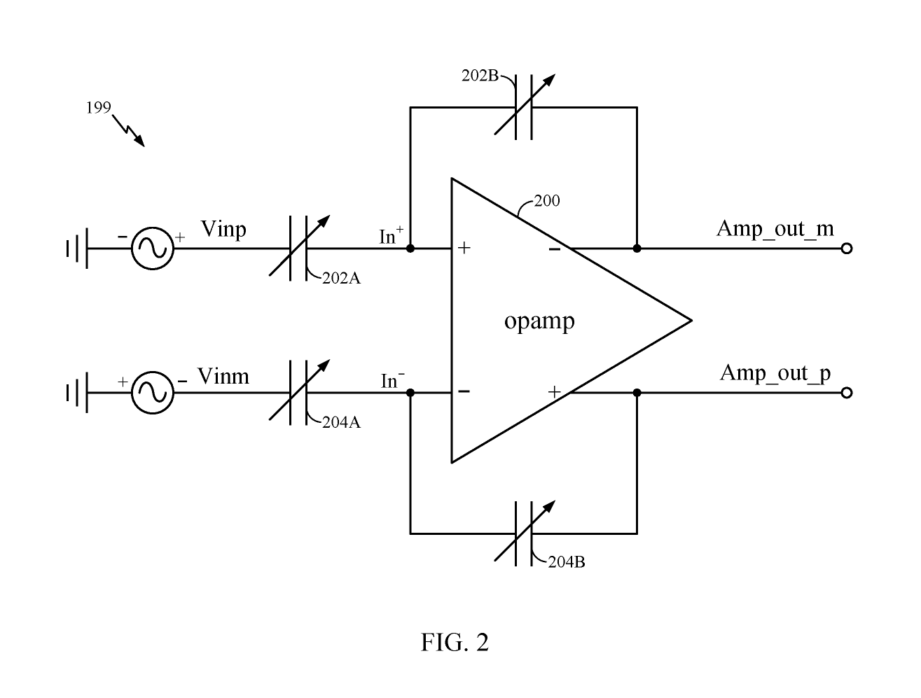

FIG. 2 is a diagram of an example PGA 199 with a plurality of gain control capacitors coupled to an amplifier 200 with fully differential outputs, in accordance with certain aspects of the present disclosure. The PGA 199 may be used as the amplifier 120 in the CODEC 100 of FIG. 1, for example. PGAs with fully differential outputs may also be used in various mixed signal applications in transmit (TX) and receive (RX) paths.

The PGA 199 may include variable capacitors 202A, 202B, 204A, and 204B used to control a gain of the PGA 199. That is, the capacitance of the variable capacitors 202A, 202B, 204A, and 204B may be controlled (e.g., by the processing system 104) to adjust the gain of the PGA to a desired value. However, increasing a gain of the PGA, resulting in a decrease of feedback network gain β of the PGA, may in turn decrease the corresponding unity gain frequency (UGF) of the PGA. This may have an adverse effect on certain parameters such as total harmonic distortion (THD) and intermodulation distortion (IMD). THD is a measure of distortion produced by an amplifier as measured in terms of the harmonics of the sinusoidal signal the amplifier produces. IMD generally refers to the amplitude modulation of signals containing two or more different frequencies, which may be due to nonlinearities in a system. The intermodulation between each frequency component may form additional signals at harmonic frequencies (integer multiples) of either component, as well as at the sum and difference frequencies of the original frequencies and at multiples of those sum and difference frequencies.

Compensation capacitors may be used in a PGA to improve stability of the PGA by increasing phase margin (PM). For example, the PM of the PGA 199 may be increased by adding compensation capacitors across an amplification stage of the amplifier 200 in the PGA. In this configuration, the compensation capacitors take advantage of the Miller Effect, which increases the effective capacitance of the compensation capacitors and helps to increase stability of the PGA 199. Accordingly, compensation capacitors may also be referred to as Miller capacitors.

Adjusting a total compensation capacitance of a PGA affects the bandwidth and UGF of the PGA. Therefore, one solution to maintain a constant UGF when changing a gain of the PGA may be to discretely reduce the total capacitance of the compensation capacitor(s) of the PGA with each gain step to maintain a constant UGF according to the following equation:

$$UGF = \frac{{g}_{m} β}{2 π {C}_{c}}$$

However, discretely reducing the compensation capacitance of the PGA with each gain step may have an adverse effect on the PGA stability and PM.

Compensation capacitors not only increase stability in differential mode (DM), but also increase stability of a common-mode (CM) loop of the PGA. Thus, to address the stability of the CM loop worsening with increased gain due to a reduction in compensation capacitance (e.g., to maintain constant UGF), the DM compensation capacitance and transconductance (gₘ) may be increased such that the CM loop stability is not adversely impacted. However, this solution may be inefficient with respect to power and area consumption. Moreover, this solution may be difficult to realize once the gain step delta exceeds about 20 dB. In addition, the CM UGF may be reduced unnecessarily at low gain modes and, therefore, may degrade the performance of the PGA by, for example, affecting even-order harmonic distortion.

Another solution entails reducing the CM UGF (and gain) sufficiently low such that the CM loop is always stable. However, with this solution, the CM UGF and the loop gain may be sacrificed at lower and higher gain steps, respectively. Lower CM bandwidth (BW) can alter the THD/IMD performance in the case of pseudo-differential input and/or any CM kickback from the load (e.g., the ADC 102 of FIG. 1). As used herein, a “pseudo-differential input” generally refers to a scenario in which a true differential input signal between two input nodes sits on top of a common mode DC input for these nodes (i.e., one input node (e.g., Vinm in FIG. 2) has the CM DC potential and the other input node (e.g., Vinp) has a potential at the sum of the differential input signal voltage and the CM DC potential). Moreover, the CM offset may increase due to low direct current (DC) gain, which may deplete the headroom of the output stage of the PGA.

Certain aspects of the present disclosure generally relate to a PGA configured to compensate, or at least adjust, for a CM loop of the PGA in a power and area efficient manner. Moreover, certain aspects of the present disclosure allow for improving the differential loop and CM feedback (CMFB) performance in an independent manner such that optimization of the differential loop does not compromise the CMFB, and vice versa. Moreover, certain aspects of the present disclosure allow for gain adjustment of the PGA (e.g., using variable capacitors 202A, 202B, 204A, and/or 204B) while maintaining a constant CM UGF across different gain settings, as well as providing other advantages discussed in more detail herein.

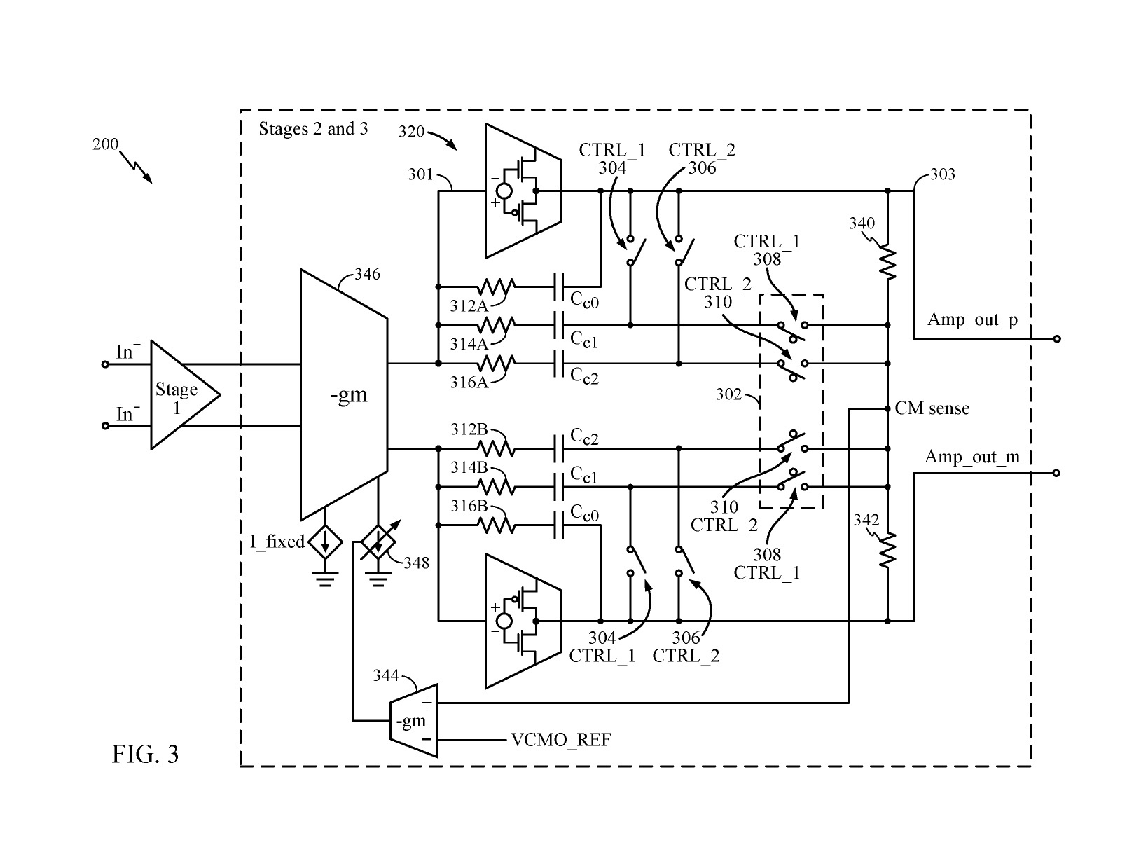

FIG. 3 illustrates an example implementation of the amplifier 200 in the PGA 199 configured to adjust a differential mode compensation capacitance with reduced impact to CM compensation capacitance, in accordance with certain aspects of the present disclosure. The amplifier 200 may include an inverting amplification stage 320 having at least one compensation capacitor C_{C0}, C_{C1}, C_{C2} (collectively “compensation capacitors C_{C}”) connected between an input node 301 and an output node 303 of the inverting amplification stage 320. In certain aspects, the compensation capacitors C_{C} may be connected with the input node 301 of the inverting amplification stage 320 through respective resistors 312A, 312B, 314A, 314B, 316A, and 316B. In certain aspects, the compensation capacitors C_{C} may be DM compensation capacitors, and the inverting amplification stage 320 may reconfigure the DM compensation capacitors C_{C} into CM compensation capacitors. That is, instead of disconnecting the compensation capacitors to reduce the compensation capacitance of the inverting amplification stage 320 in response to a gain change of the PGA, the compensation capacitors can be reconfigured as CM compensation capacitors. For example, the compensation capacitors may be coupled between a respective input of the inverting amplification stage 320 and a node used to sense the CM potential (labeled “CM sense”) of the inverting amplification stage 320.

In this configuration, the potential at the CM sense node may be equal to the actual CM voltage of the inverting amplification stage 320 because the CM sense node is coupled across the amplifier's differential outputs via series resistors 340 and 342, for example. Resistors 340 and 342 may have substantially the same resistance. In certain aspects, a switched capacitor circuit may be used instead of resistors 340 and 342 to sense the actual CM voltage and apply the actual CM voltage to the CM sense node. The switched capacitor circuit may comprise switches and capacitors. For certain aspects, each of resistors 340 and 342 may be replaced by a capacitor and two or more switches in series, for example. The switches in the switched capacitor circuit may be controlled by one or more control signals (e.g., clock signals) from a controller or a processor, such as the processing system 104 of FIG. 1.

An example circuit for adjusting the compensation capacitance may include: (1) a switch between the compensation capacitor(s) and the output node 303 of the amplification stage 320; and (2) another switch between the compensation capacitor(s) and the CM sense node. That is, the inverting amplification stage 320 includes at least one switch (shown in switching configuration 302) configured to connect the compensation capacitor(s) with the CM sense node of the inverting amplification stage 320 of the amplifier 200 in the PGA 199. In this configuration, the CM sense node is also the DM reference potential of the PGA. Switches 304 are controlled via a control signal CTRL_1 and have corresponding switches 308 that are also controlled based on the control signal CTRL_1. However, as illustrated, switches 308 may be configured with inverse control logic with respect to switches 304. For example, when switches 304 are closed, switches 308 are open and vice versa. Similarly, when switches 306 are controlled via control signal CTRL_2 and have corresponding switches 310 that are also controlled via control signal CTRL_2, but have inverse control logic.

For the highest gain setting of the PGA, switches 304 and 306 may be open, and for the lowest gain setting of the PGA, switches 304 and 306 may be closed. That is, switches 304 and 306 may be opened or closed in response to the gain setting based on the logic level of control inputs CTRL_1 and CTRL_2. When switches 304 and 306 are open and switches 308 and 310 are closed, the compensation capacitors C_{C1} and C_{C2} are connected with the CM sense node. Thus in this configuration, compensation capacitors C_{C1} and C_{C2} act as CM compensation capacitors, instead of as DM compensation capacitors.

Therefore, for the lowest gain setting of the PGA when switches 304 and 306 are closed and switches 308 and 310 are open, the DM compensation capacitance may be equal to the CM compensation capacitance, which may be equal to the sum of the capacitances of the compensation capacitors C_{C0}, C_{C1}, and C_{C2}.

For the highest gain setting when switches 304 and 306 are open and switches 308 and 310 are closed, the DM compensation capacitance may be equal to the capacitance of compensation capacitor C_{C0}. However, the CM compensation capacitance may be equal to the sum of the capacitances of compensation capacitors C_{C0}, C_{C1}, and C_{C2}. That is, the CM compensation capacitance remains unchanged between the highest and lowest gain settings. Thus, the DM compensation capacitance may be adjusted to maintain a constant CM UGF across different gain settings without impacting the CM compensation capacitance, and thus, helping to maintain stability of the PGA 199.

In certain aspects, switches 304 may be closed, and switches 306 may be open, during an intermediary gain setting of the PGA 199. During the intermediary gain setting, the DM compensation capacitance may be about equal to the sum of the capacitances of compensation capacitors C_{C0}, and C_{C1}, while the CM compensation capacitance may be equal to the sum of the capacitances of capacitors C_{C0}, C_{C1}, and C_{C2}. That is, the CM compensation capacitance remains unchanged in the intermediary gain setting as compared to the lowest and highest gain settings described above.

In certain aspects, the CM sense node may be used for CMFB. For example, the CM voltage of the PGA 199 at the CM sense node may be sensed by an amplifier 344 (e.g., a negative transconductance (−gm) amplifier) and compared with a CM reference potential (VCMO_REF) representing a desired CM voltage for the PGA 199. Based on the comparison, the amplifier 344 may drive a variable current source 348 configured to sink a current from another amplification stage 346 of the amplifier 200 in the PGA 199 in an effort to adjust the actual CM voltage of the PGA. That is, by adjusting the variable current source 348, the actual CM voltage of the PGA 199 may be adjusted until the actual CM voltage equals the desired CM voltage as represented by the CM reference potential.

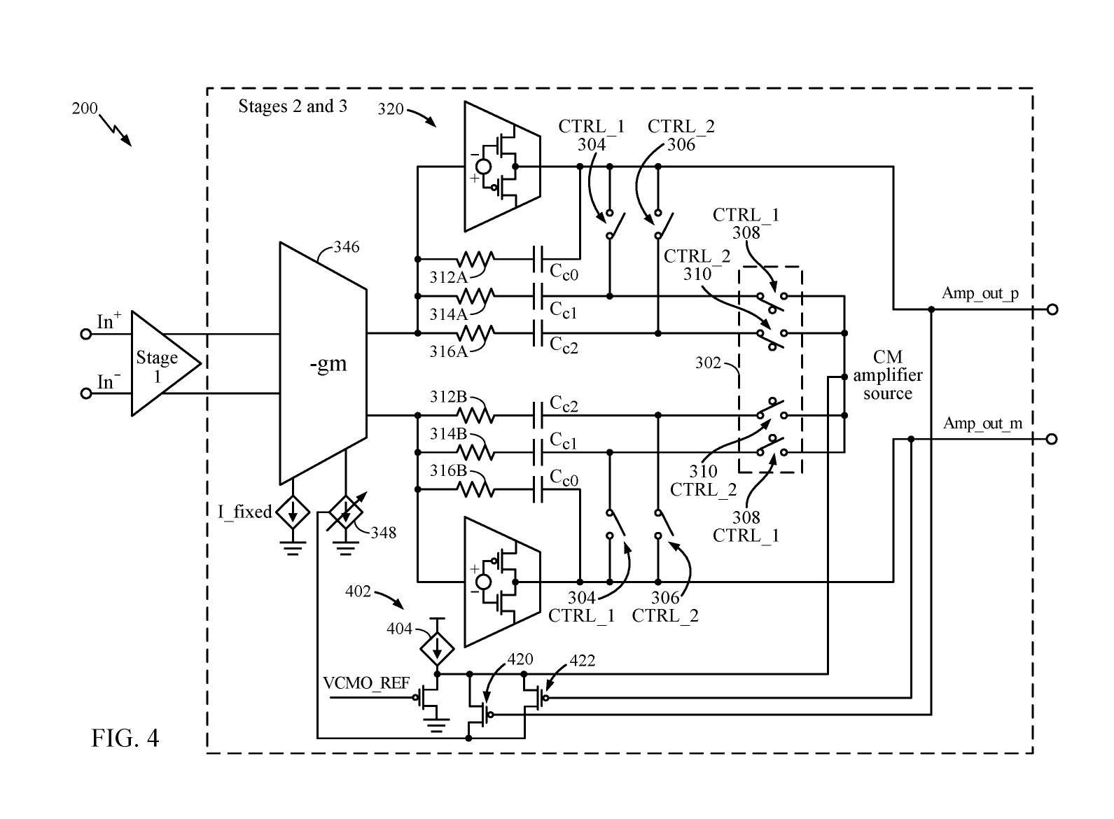

FIG. 4 illustrates another example implementation of the amplifier 200 in the PGA 199 having at least one switch (shown in switching configuration 302) inserted between compensation capacitors of the inverting amplification stage 320 of the amplifier and a node (labeled “CM amplifier source”) used as an input to a CM amplifier 402, according to certain aspects of the present disclosure. In this case, a voltage at the CM amplifier source node is a DM reference potential for the inverting amplification stage 320. That is, unlike the circuit diagram of FIG. 3, the CM amplifier source node is not coupled across the differential output of the inverting amplification stage 320 (e.g., via resistors 340 and 342). Therefore, the potential at the CM amplifier source node may not equal the actual CM potential of the inverting amplification stage 320, but rather, is the DM reference potential for the inverting amplification stage 320.

As illustrated, sources of p-channel metal-oxide semiconductor (PMOS) transistors 420 and 422 in the CM amplifier 402 are connected with the CM amplifier source node such that one or more of the compensation capacitors coupled to the CM amplifier source node can stabilize the CM loop. The CM amplifier 402 may be configured to sense a CM voltage of the differential output of the amplifier 200 via the gates of the PMOS transistors 420 and 422. The CM voltage as sensed by the PMOS transistors 420 and 422 may be compared to a CM reference potential (VCMO_REF) representing a desired CM voltage for the PGA 199, based on which the CM amplifier 402 may adjust the actual CM voltage for the differential output of the PGA. The CM amplifier 402 may also include a current source 404 configured to bias the CM amplifier 402.

In this case, when the logic level of control signals CTRL_1 and CTRL_2 are configured to close switches 308 and 310 during the highest gain setting, compensation capacitors C_{C1} and C_{C2} are connected to the CM amplifier source node via switches 308 and 310 and act as CM compensation capacitors, instead of as DM capacitors (based on the logic level of control signals CTRL_1 and CTRL_2). Thus, during the lowest gain setting of the PGA 199 when switches 304 and 306 are closed and switches 308 and 310 are open, the DM compensation capacitance may be about equal to the CM compensation capacitance, which may be equal to the sum of the capacitances of compensation capacitors C_{C0}, C_{C1}, and C_{C2}.

During the highest gain setting of the PGA 199 when switches 304 and 306 are open and switches 308 and 310 are closed, the DM compensation capacitance may be about equal to the capacitance of compensation capacitor C_{C0}. However, the CM compensation capacitance may be equal to the sum of the capacitances of the compensation capacitors C_{C0}, C_{C1}, and C_{C2}. That is, the CM compensation capacitance remains unchanged between the highest and the lowest gain settings. Thus, the CM UGF remains constant across gain settings.

In certain aspects, switches 306 may be closed, and switches 304 may be open, during an intermediary gain setting of the PGA 199. During the intermediary gain setting, the DM compensation capacitance may be about equal to the sum of the capacitances of compensation capacitors C_{C0}, and C_{C2}, while the CM compensation capacitance may be about equal to the sum of the capacitances of the compensation capacitors C_{C0}, C_{C1}, and C_{C2}. That is, the CM compensation capacitance remains unchanged as compared to the lowest and highest gain settings described above.

Aspects of the present disclosure allow CMFB loop optimization across different gain modes such that performance parameters (e.g., linearity dependent on CM kickback) are not impacted due to CM UGF variation across gains, reducing design and verification efforts.

Aspects of the present disclosure also allow for a more accurate control of the CM voltage of the amplifier. Moreover, the CM offset due to the CM loop can be reduced because the CM loop can de designed more aggressively. For example, the CM offset may be reduced by a factor of 5 (e.g., from a standard deviation (σ) of 15 mV to about 3 mV). In addition, the DM loop can be optimized independently from the CM loop to increase performance without degrading the CMFB stability and accuracy. Aspects of the present disclosure prevent the bandwidth of the PGA being sacrificed for the CMFB loop at lower gain modes, with a small amount of area consumption.

Although only two compensation capacitors associated with two sets of corresponding switches (one set including switches 304 and 308 and the other set including switches 306 and 310) are illustrated in the examples of FIGS. 3 and 4, more or less than two compensation capacitors and associated sets of corresponding switches may be used. This number may depend on the number of different gain steps of the PGA. For ease of description, only two compensation capacitors and associated sets of corresponding switches are described, but the circuit can be configured to include a different number of compensation capacitors with corresponding switches.

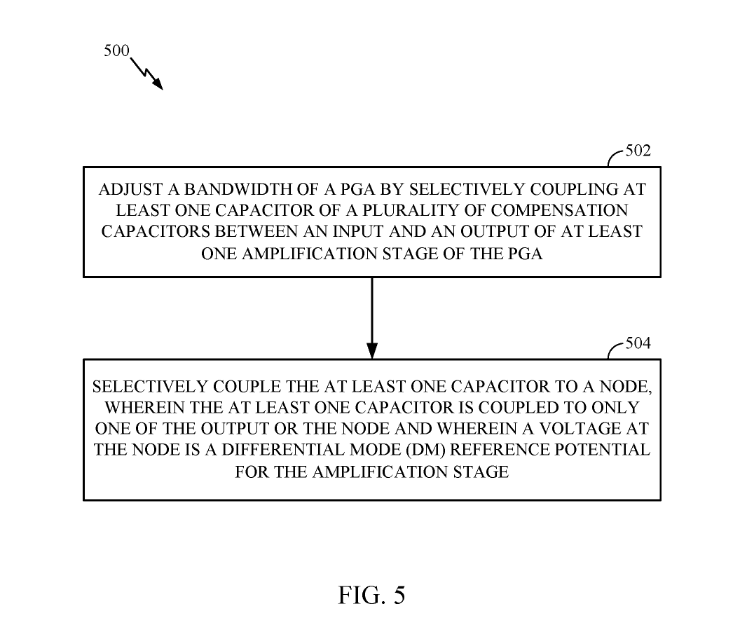

FIG. 5 is a flow diagram of example operations 500 for controlling a PGA, in accordance with certain aspects of the present disclosure. The operations 500 may be performed, for example, by a circuit, such as the amplifier 200 of FIG. 3 or FIG. 4.

The operations 500 may begin, at block 502, with the circuit adjusting a bandwidth of the PGA by selectively coupling at least one capacitor of a plurality of compensation capacitors between an input and an output of at least one amplification stage of the PGA. At block 504, the circuit may selectively couple the at least one capacitor to a node. The at least one capacitor may be coupled to only one of the output or the node, and a voltage at the node is a differential mode (DM) reference potential for the amplification stage.

In certain aspects, the DM reference potential is a CM voltage of the PGA. In this case, the operations 500 may further include comparing the CM voltage of the PGA with a CM reference potential and adjusting the CM voltage of the PGA based on the comparison.

In other aspects, the operations 500 further include comparing an effective CM voltage of the PGA with a CM reference potential via a CM amplifier (e.g., CM amplifier 402) and adjusting the effective CM voltage of the PGA based on the comparison via the CM amplifier. In this case, the node may be coupled to the CM amplifier.

According to certain aspects, adjusting the bandwidth of the PGA at block 502 involves opening a first switch connected between the at least one capacitor and the output. In certain aspects, selectively coupling the at least one capacitor to the node at block 504 entails closing a second switch connected between the at least one capacitor and the node.

According to certain aspects, adjusting the bandwidth of the PGA at block 502 includes closing a first switch connected between the at least one capacitor and the output. In certain aspects, selectively coupling the at least one capacitor to the node at block 504 entails opening a second switch connected between the at least one capacitor and the node.

In certain aspects, adjusting the bandwidth of the PGA may be based on a gain of the PGA.

In certain aspects, the operations 500 may further involve adjusting a gain of the PGA by adjusting a capacitance of at least one gain adjustment capacitor coupled across an input and an output of the PGA. In this case, the output of the PGA may be the output of the at least one amplification stage.

In certain aspects, the compensation capacitors are configured to increase a phase margin of the PGA.

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

Means for adjusting, means for opening, and means for closing may comprise a controller or a processor, such as the processing system 104 of FIG. 1. Means for selectively coupling may comprise a switch, such as the switches 304, 306 or 308. Means for comparing may comprise an amplifier, such as the amplifier 344 of FIG. 3, or the CM amplifier 402 of FIG. 4. Means for adjusting, may comprise an amplifier, such as the amplifier 344 of FIG. 3, or the CM amplifier 402 of FIG. 4 and/or the variable current source 348 of FIG. 4.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g., accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A programmable gain amplifier (PGA), comprising:
at least one amplification stage having an input and an output;
a plurality of compensation capacitors;
at least one first switch configured to selectively couple at least one capacitor of the plurality of compensation capacitors between the input and the output of the at least one amplification stage; and
at least one second switch configured to selectively couple the at least one capacitor to a node, wherein the at least one capacitor is coupled to only one of the output or the node and wherein a voltage at the node is a differential mode (DM) reference potential for the at least one amplification stage.

2. The PGA of claim 1, wherein the DM reference potential is a common-mode (CM) voltage of the PGA and wherein the PGA further comprises an amplifier coupled to the node and configured to:
compare the CM voltage of the PGA with a CM reference potential; and
adjust the CM voltage of the PGA based on the comparison.

3. The PGA of claim 1, wherein the PGA further comprises a common-mode (CM) amplifier coupled to the node and configured to:
compare an effective CM voltage of the PGA with a CM reference potential; and
adjust the effective CM voltage of the PGA based on the comparison.

4. The PGA of claim 3, wherein the CM amplifier comprises:
a first transistor, wherein a gate of the first transistor is controlled via the CM reference potential;
a second transistor, wherein a gate of the second transistor is controlled via a positive differential output of the PGA; and
a third transistor, wherein:
a gate of the third transistor is controlled via a negative differential output of the PGA;
sources of the first, second, and third transistors are coupled to the node;
a drain of the second transistor is coupled to a drain of the third transistor; and
a voltage at the drains of the second and third transistors is used to adjust the effective CM voltage of the PGA based on the comparison.

5. The PGA of claim 1, wherein each of the plurality of compensation capacitors are coupled to the input of the at least one amplification stage through a respective resistor.

6. The PGA of claim 1, wherein the at least one first switch and the at least one second switch are controlled based on a gain of the PGA.

7. The PGA of claim 1, further comprising at least one gain adjustment capacitor coupled across an input and an output of the PGA, wherein a gain of the PGA is adjusted by adjusting a capacitance of the at least one gain adjustment capacitor.

8. The PGA of claim 7, wherein the output of the PGA is the output of the at least one amplification stage.

9. The PGA of claim 1, further comprising a plurality of resistors coupled across a differential output of the at least one amplification stage, wherein the node comprises a node between the plurality of resistors.

10. The PGA of claim 1, further comprising a switched capacitor circuit coupled to a differential output of the at least one amplification stage, wherein the switched capacitor circuit comprises a plurality of switches and a plurality of capacitors and wherein the node comprises a node between the plurality of capacitors in the switched capacitor circuit.

11. The PGA of claim 1, wherein the plurality of compensation capacitors are configured to increase a phase margin of the PGA.

12. A method for operating a programmable gain amplifier (PGA), comprising:
adjusting a bandwidth of the PGA by selectively coupling at least one capacitor of a plurality of compensation capacitors between an input and an output of at least one amplification stage of the PGA; and
selectively coupling the at least one capacitor to a node, wherein the at least one capacitor is coupled to only one of the output or the node and wherein a voltage at the node is a differential mode (DM) reference potential for the at least one amplification stage.

13. The method of claim 12, wherein the DM reference potential is a common-mode (CM) voltage of the PGA and wherein the method further comprises:
comparing the CM voltage of the PGA with a CM reference potential; and
adjusting the CM voltage of the PGA based on the comparison.

14. The method of claim 12, further comprising:
comparing an effective common-mode (CM) voltage of the PGA with a CM reference potential via a CM amplifier coupled to the node; and
adjusting the effective CM voltage of the PGA based on the comparison via the CM amplifier.

15. The method of claim 12, wherein adjusting the bandwidth of the PGA comprises opening a first switch connected between the at least one capacitor and the output.

16. The method of claim 15, wherein selectively coupling the at least one capacitor to the node comprises closing a second switch connected between the at least one capacitor and the node.

17. The method of claim 12, wherein adjusting the bandwidth of the PGA comprises closing a first switch connected between the at least one capacitor and the output.

18. The method of claim 17, wherein selectively coupling the at least one capacitor to the node comprises opening a second switch connected between the at least one capacitor and the node.

19. The method of claim 12, wherein adjusting the bandwidth of the PGA is based on a gain of the PGA.

20. The method of claim 12, further comprising adjusting a gain of the PGA by adjusting a capacitance of at least one gain adjustment capacitor coupled across an input and an output of the PGA.

21. The method of claim 20, wherein the output of the PGA is the output of the at least one amplification stage.

22. The method of claim 12, wherein the plurality of compensation capacitors are configured to increase a phase margin of the PGA.

23. An apparatus for amplifying a signal, comprising:
means for adjusting a bandwidth of the apparatus by selectively coupling at least one capacitor of a plurality of compensation capacitors between an input and an output of at least one amplification stage of the apparatus; and
means for selectively coupling the at least one capacitor to a node, wherein the at least one capacitor is coupled to only one of the output or the node and wherein a voltage at the node is a differential mode (DM) reference potential for the at least one amplification stage.

24. The apparatus of claim 23, wherein the DM reference potential is a common-mode (CM) voltage of the apparatus and wherein the apparatus further comprises:
means for comparing the CM voltage of the apparatus with a CM reference potential; and
means for adjusting the CM voltage of the apparatus based on the comparison.

25. The apparatus of claim 23, further comprising:
means for comparing an effective CM voltage of the apparatus with a CM reference potential; and
means for adjusting the effective CM voltage of the apparatus based on the comparison, wherein the node is coupled to the means for comparing.

26. The apparatus of claim 23, wherein the means for adjusting the bandwidth of the apparatus is configured to open a connection between the at least one capacitor and the output.

27. The apparatus of claim 26, wherein the means for selectively coupling the at least one capacitor to the node is configured to make a connection between the at least one capacitor and the node.

28. The apparatus of claim 23, wherein the means for adjusting the bandwidth of the apparatus is configured to make a connection between the at least one capacitor and the output.

29. The apparatus of claim 28, wherein the means for selectively coupling the at least one capacitor to the node is configured to open a connection between the at least one capacitor and the node.

30. The apparatus of claim 23, further comprising means for adjusting a gain of the apparatus, wherein the means for adjusting the bandwidth of the apparatus is configured to adjust the bandwidth based on the gain of the apparatus.
